(19) United States
(12) Patent Application Publication
(10) Pub. No.: US 2012/0158346 A1
(43) Pub. Date: Jun. 21, 2012

(54) IDDQ TESTING OF CMOS DEVICES

(75) Inventor: Chinsong Sul, Mountain View, CA (US)

(73) Assignee: SILICON IMAGE, INC., Sunnyvale, CA (US)

(21) Appl. No.: 13/298,001

(22) Filed: Nov. 16, 2011

Related U.S. Application Data
(60) Provisional application No. 61/424,572, filed on Dec. 17, 2010.

(51) Int. Cl. G06F 19/00; G01R 31/26

(52) U.S. Cl. 702/119; 324/762.02

(57) ABSTRACT

IDDQ testing of CMOS devices. An embodiment of a method includes applying a test pattern of inputs to a device, the device including one or more CMOS (Complementary Metal-Oxide Semiconductor) transistors, and obtaining current measurements for the device, each of the current measurements being a measurement of a current after applying an input of the test pattern to the device. A filter function is applied to the current measurements, applying the filter function including separating defect current values from the current measurements. The method further includes determining whether a defect is present in the device based at least in part on a comparison of the defect current values with a threshold value.

### RELATED APPLICATIONS

This application is related to and claims priority to U.S. Provisional Patent Application No. 61/424,572, filed Dec. 17, 2010, and such application is incorporated herein by reference.

### TECHNICAL FIELD

Embodiments of the invention generally relate to the field of testing of semiconductor devices and, more particularly, to a method, apparatus, and system for IDDQ testing of CMOS devices.

### BACKGROUND

In the production of semiconductor devices, a significant number of devices may prove to be defective. Because of the nature of generation of semiconductor device, defective devices generally will manifest themselves quickly. For this reason, the testing of such devices is important to identity the defective devices.

However, testing has practical limitations. If a manufacturer or lab cannot test semiconductor devices quickly, accurately, and at reasonable cost, then the testing will not be possible.

Testing of CMOS (Complementary Metal-Oxide Semiconductor) for manufacturing defects may include IDDQ testing. IDDQ testing is a current-based test method and is known to be effective for detecting faults that can be missed by commonly used structural tests such as stuck-at and delay tests. Such testing measures the supply current (Idd) in a quiescent state via various processes. IDDQ testing may be effective for larger scale devices, such as 0.18 μm or larger CMOS, where the leakage current is significantly smaller than the modeled defect current.

However, IDDQ testing is challenging in advanced manufacturing processes, such as 0.13 μm or smaller devices, due to increased leakage currents and significant variations that occur across wafers. Test development costs of IC (integrated circuit) devices that are fabricated in such an advanced manufacturing process (which may be referred to as a “nanometer process”) tend to increase because of required test complexity. The nanometer process offers performance improvement and a greater number of transistors to be implemented on each die, but also introduces new failure mechanisms that require testing. In order to cope with increasing test cost, less expensive test alternatives are very useful. The effectiveness of IDDQ testing of nanometer devices is made difficult by increased leakage currents and their variations across wafers.

### SUMMARY

A method and apparatus are provided for IDDQ testing of CMOS devices.

In a first aspect of the invention, an embodiment of a method includes applying a test pattern of inputs to a device, the device including one or more CMOS (Complementary Metal-Oxide Semiconductor) transistors, and obtaining current measurements for the device, each of the current measurements being a measurement of a current after applying an input of the test pattern to the device. A filter function is applied to the current measurements, applying the filter function including separating defect current values from the current measurements, and a determination is made whether a defect is present in the device based at least in part on a comparison of the defect current values with a threshold value.

In a second aspect of the invention, an embodiment of a test apparatus includes an interface for a device under test, the interface being used to apply a set of inputs to a device containing one or more CMOS devices, and logic to apply a test pattern of inputs to the device under test. The apparatus further includes a current measurement unit to measure a current of the device for each input of the set of inputs, logic to separate defect current from the measured currents including application of a noise filter function to the current measurements, and logic to determine existence of a defect in the device under test based at least in part on the defect current.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is an illustration of a non-defective CMOS inverter circuit;

FIG. 2 is an illustration of a defective CMOS inverter circuit for detection by an embodiment of a fault detection method, apparatus, or system;

FIG. 3 is a flowchart to illustrate an embodiment of a process for IDDQ testing of advanced devices;

FIG. 4 is an illustration of the application of a filter function in an embodiment of a determination of a current;

FIGS. 5A and 5B illustrate noise filter functions utilized in an embodiment of a defect current detection process, apparatus, or system;

FIGS. 6A and 6B illustrate a measured current function and filter function in an embodiment of a process for extraction of a defect current;

FIG. 7 illustrates an embodiment of convolution in a method to recover or extract defect current;

FIG. 8 illustrates multiple filter functions applied in series in an embodiment of a process to reduce noise currents;

FIG. 9 is an illustration of defect and noise currents addressed in an embodiment of defect current detection;

FIG. 10 is an illustration of an embodiment of a method for application of filtering to current measurements;

FIGS. 11A and 11B illustrate random filter function generation in an embodiment of defect current detection;

FIG. 12 illustrates a recurrence equation for an embodiment of a method, apparatus, or system providing defect current detection;

FIG. 13 illustrates a filter function for higher order k defined using convolution for an embodiment of a method, apparatus, or system providing defect current detection;

FIG. 14, illustrates calculation of coefficients in an embodiment of a process for defect current detection;

FIG. 15 illustrates a filter function for an embodiment of detection of defect currents; and

FIG. 16 illustrates an embodiment of an apparatus or system for the detection of defective components utilizing IDDQ measurements.

### DETAILED DESCRIPTION

Embodiments of the invention are generally directed to IDDQ testing of CMOS devices.

As used herein:

“IDDQ” means testing of semiconductor devices including the measurement of leakage current (I_{DD}) in a quiescent state.

In some embodiments, an apparatus, system, and method provide for IDDQ testing of semiconductor devices in which testing includes separation of leakage current from intended IDDQ current. In some embodiments, a novel IDDQ test method is provided for nanometer IC designs. In some embodiments, an IDDQ test method may be utilized to mitigate the difficulty of testing in presence of large leakage current and its significant variation across wafers.

In some embodiments, an IDDQ test method is provided for IC devices fabricated in advanced manufacturing processes, in which there may be increased leakage current and process variation. In some embodiments, an IDDQ test system is implemented to mitigate difficulties in IDDQ testing in the presence of high leakage current and significant variation between devices.

In some embodiments, a testing process includes removal of common leakage currents from measured values, while detected defect currents are amplified. In some embodiments, the amplified defect current may then be further amplified by current aggregation to assist in separating good circuits from defective circuits. In some embodiments, an IDDQ testing method is provided to increase the observability of a defect current that is captured in a small set of IDDQ current measurements, without requiring the measurement of additional currents using the current test or automatic test equipment (ATE).

In some embodiments, a testing method and system applies signal and system theory to an IDDQ test. An embodiment of a testing method considers measured currents as input signals and the leakage current reduction function as a system. When the input signals are applied to the system, output of system can be described by convolution of input signals and the leakage reduction function. In some embodiments, a method reduces the leakage effect and amplifies the defect current buried in the measured current by the reduction function via the convolution, where the defect current may be further amplified by aggregation of amplified defect current resulting from convolution, the convolution involving a sum of products of signal components that constitute input signals and the reduction function.

In some embodiments, a current may be measured by ATE (Automatic Test Equipment) or other apparatus or system by sensing an IDDQ current at a steady state after a test pattern is applied. In normal operation, the test time that is expended for IDDQ testing is dominated by the time required for current measurement at the tester or ATE. Under an embodiment in which an IDDQ current is determined, the time that is required to compute convolution and aggregation generally will be insignificant compared to the IDDQ current measurement time, and thus the value determinations may be carried out concurrently with the current measurements.

In some embodiments, the measured IDDQ current may be considered to be a composite electrical quantity whose components are interpreted as a “signal component” and a “noise component”. In this view, the signal component denotes the wanted component of the current, and the noise component the unwanted component. In an embodiment of an IDDQ test method that is intended to reduce leakage current effect and to increase observability of current caused by IDDQ defects (the defect current), the leakage current constitutes the noise component and the defect current constitutes the signal component. A set of non-zero signal and noise components may be defined as a function by assuming zero everywhere else, which may be expressed with the notation f(k). The measured current and the noise current can similarly be denoted as Iₘ(k) and I_{c}(k), respectively.

In some embodiments, an IDDQ method is provided to target the defect currents caused by manufacturing defects, such as shorts and opens on transistors, in advanced process devices. Catastrophic failures that occur in such devices, such as power and ground short defects, can immediately be detected from any current measurement, but other defect currents are more subtle and may be lost in the current variation of such devices.

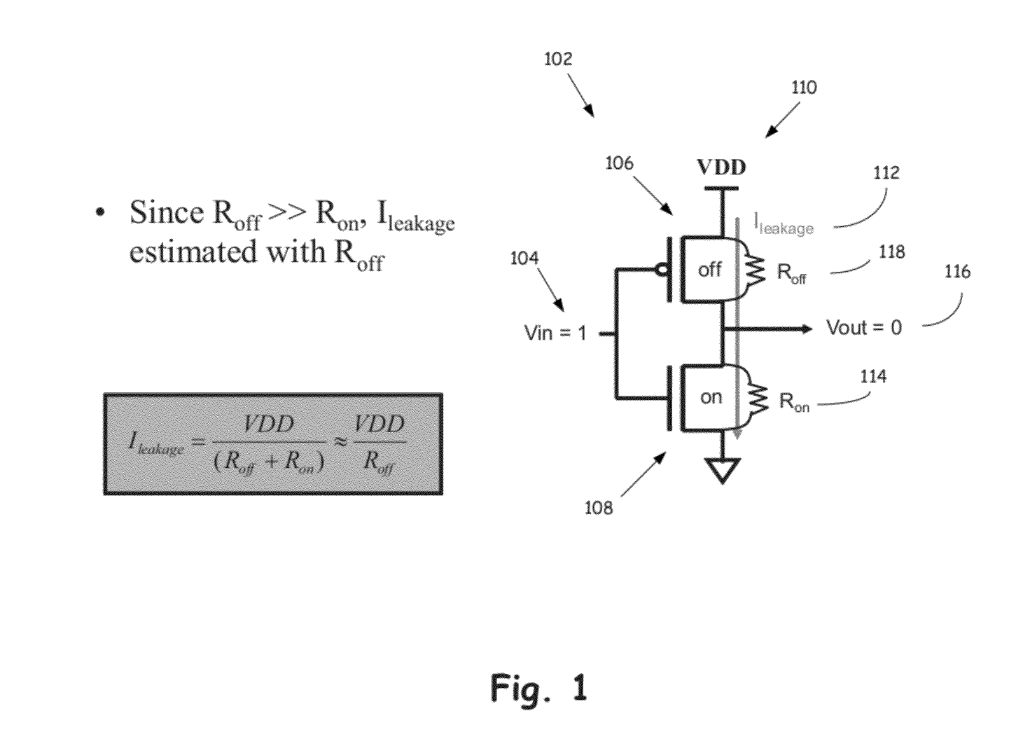

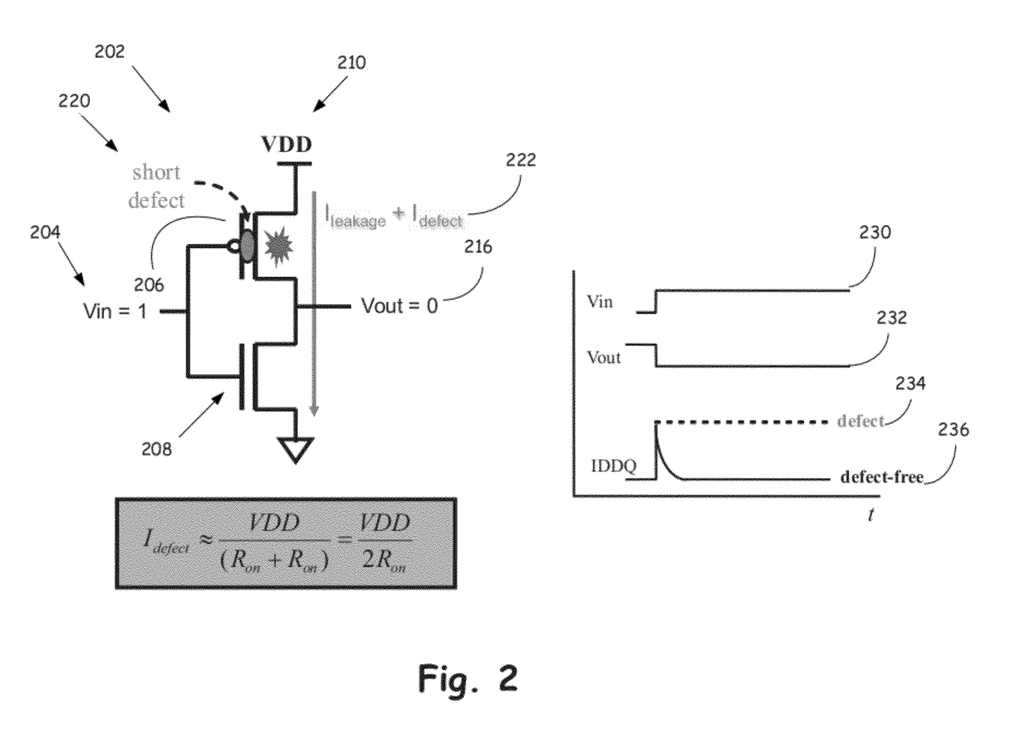

As an example, leakage (noise) currents are illustrated in FIGS. 1 and 2. FIG. 1 is an illustration of a non-defective CMOS inverter circuit 102. FIG. 2 is an illustration of a defective CMOS inverter circuit 202 for detection by an embodiment of a fault detection method, apparatus, or system. In FIGS. 1 and 2, if input voltage (104 in FIGS. 1 and 204 in FIG. 2) is biased to logic ‘1’, the NFET (N-type field effect transistor) (106, 206) that is connected to the ground is turned on and the PFET (P-type field effect transistor) (108, 208) is turned off, producing the output voltage (116, 216) of a logical ‘0’. If the input voltage (104, 204) is biased to ‘0’, however, the PFET (108, 208) and NFET (106, 206) are turned on and off respectively, producing a logical ‘1’ at the output (116,216). An ideal current characteristic of a CMOS circuit would theoretically allow current to flow during output transition, for example, from logical ‘1’ to ‘0’, with no current flowing when the output reaches steady state. In actual operation, however, a small current flows through a CMOS transistor at steady state. This small current is the “leakage current”, and the amount of the leakage current depends on the resistance of the transistors that are turned on and off.

Because the resistance of a transistor that has been turned off (R_{off}) 118 is significantly larger than that of a transistor that has been turned on (Rₒₙ) 114, the leakage current can be approximated with R_{off} using Ohm's law as shown in FIG. 1. The total leakage current (I_{leakage}) 112 of a device under test (DUT) may be obtained by adding the currents from all leakage paths in the DUT. There are potentially many leakage paths in a large design, such as, for example, a system-on-chip (SOC) device that contains a very large number of transistor devices. Each logic gate may, for example, be considered to be an independent leakage path. For this reason, the total leakage current of a circuit with potentially millions of gates can be substantially large.

In some embodiments, an implementation of an IDDQ test may target faults in the turned-off transistors of a device under test. A set of input stimuli, referred to as a test pattern, may be employed to turn on and off different subsets of transistors in the circuit. The resistance R_{off} then will act to reduce current flow during a steady state. The IDDQ defect can change resistance at steady state, and allow a significantly larger current than would be expected to flow from power source (V_{DD}) (110, 210) to ground.

If, for example, a short defect 220 is present in the PFET 206 as shown in FIG. 2, the PFET 206 is turned on permanently and the resistance is changed permanently to Rₒₙ. However, other defects, such as gates that remain open, can cause transistors to be partially turned on. The resistance of partially turned on transistors can be larger than Rₒₙ but still significantly smaller than R_{off}. If, for example, the NFET 208 is turned on by forcing input stimulus Vᵢₙ=‘1’, a large current can flow from V_{DD} 210 to ground at steady state. Such defect currents (I_{defect}) 222 can similarly be estimated with, for example, I_{defect} being estimated as V_{DD} divided by twice Rₒₙ, as shown in FIG. 2. FIG. 2 also illustrates the currents graphically. If, for example, Vᵢₙ is a logical ‘1’ value 230 and Vₒᵤₜ 232 thus is ‘0’, then, after an initial spike, the steady state IDDQ current for a defect-free device will drop to, for example, a steady state current level 236. However, for a defective device, the steady state current will remain high, such as illustrated by current level 234.

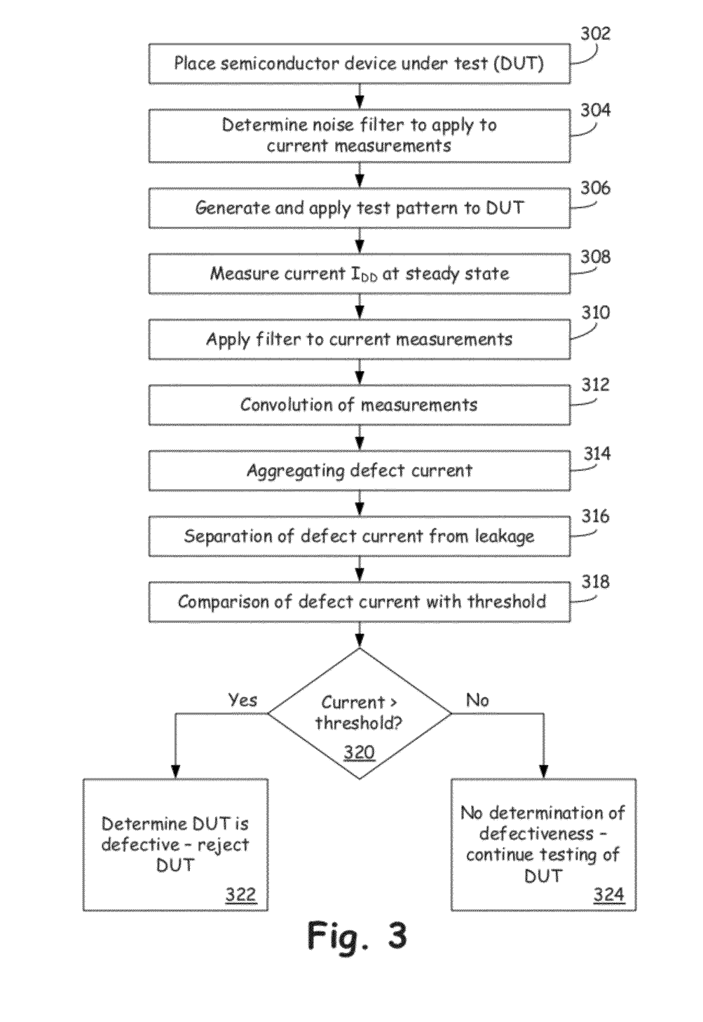

FIG. 3 is a flowchart to illustrate an embodiment of a process for IDDQ testing of advanced devices. In this illustration, a semiconductor device is connected to a testing apparatus or system as the device under test (DUT) 302. In some embodiments, a current test is applied to the DUT, but other testing may be provided together with such current testing. A determination is made regarding a noise filter function to apply to current measurements 304, where such determination may be made in the design of the testing apparatus or system. A test pattern for current testing of the DUT is generated and applied to the DUT 306. As a result of such test pattern, currents at steady state are measured from the DUT 308. The chosen filter is applied to the current measurements 310, where such application results in the convolution of the current measurements 312 and the aggregation of defect current measurements 314, resulting in separating the defect current measurements from leakage current measurements 316. The defect current is then compared to a threshold value 318. If the defect current is greater than the threshold value 320, then the DUT may be determined to be defective and rejected 322. If the defect current is not greater than the threshold value 320, then there is no determination of defectiveness of the DUT, and testing of the DUT may continue with any additional testing planned for the device 324.

The following equations define a measured current and a noise current:

$$\begin{matrix}{I}_{m} ( k ) = Ic ( k ) + a ( k ) {I}_{sat} & [ 1 ] \\ Ic ( k ) = {\sum }_{path} {I}_{leakage} ( k , path ) & [ 2 ]\end{matrix}$$

In this illustration, the measured current for test pattern k at steady state, denoted as Iₘ(k), may include a defect current and a total leakage current I_{c}(k) contributed from all leakage current paths in the circuit. The Iₘ(k) can be obtained by measuring IDDQ current after applying the k^{th} test pattern. The increased IDDQ current that is due to defects can be defined as a(k) Iₛₐₜ, where a(k)εR denotes a current contribution factor from defects. The defect current is modeled with a PFET (or NFET) saturation current, and is measured in units of the same saturation current. The I_{c}(k) may be estimated by adding leakage currents from all leakage paths in the DUT. The I_{leakage} (k, path) then denotes leakage current flowing in one of the paths in the DUT for a given test pattern k. Even if the noise current can be estimated in theory, the noise current may be considered to be random, assuming a Gaussian distribution with μ=I₀.

In some embodiments, using the definition of the currents provided in equations [1] and [2], a process is implemented to reduce the effect of I_{c}(k) so that defect current is more observable. In some embodiments, a common noise filter function is provided to reduce the effect of I_{c}(k) and to amplify defect currents to provide improved observability. An embodiment of a process further improves observability by aggregation of amplified defect currents.

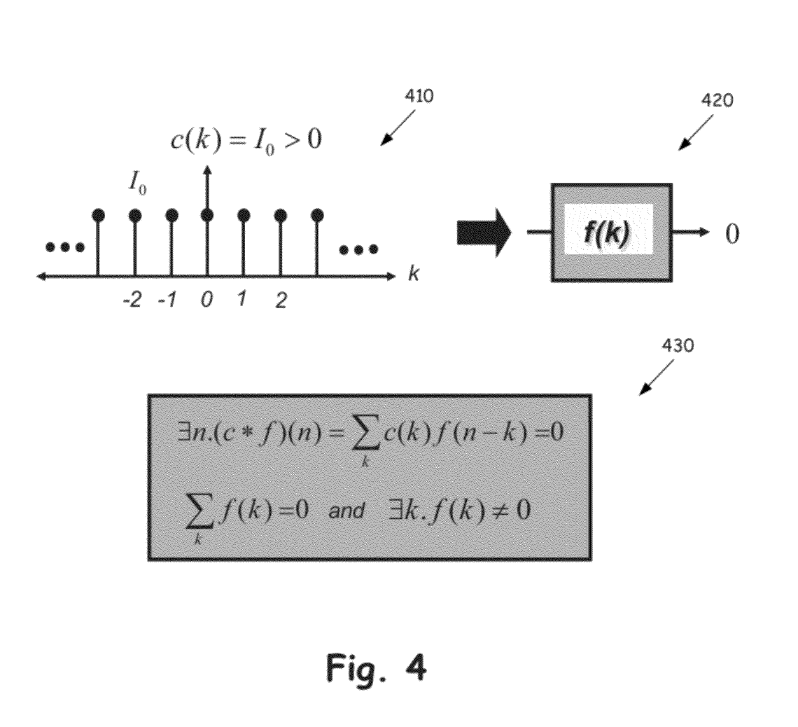

FIG. 4 is an illustration of the application of a filter function in an embodiment of a determination of a current. In this illustration, a constant function c(k)=I₀, element 410, represents an ideal I_{c}(k) that has a magnitude of I₀ for all k. If the function c(k) is applied to the input of filter function f(k) 420, the output of the desired filter function should be zero. The response of the filter function may be described by the convolution 430 as shown in FIG. 4. The convolution equation provides criteria to determine the common noise filter function. It can be shown mathematically that any solution of the convolution equation also satisfies the property that Σf(k)=0. The trivial solution, f(k)=0 for all k, is ruled out because it removes not only common noise but also signals of interest (the defect currents).

In some embodiments, alternatively a weighted summation may be employed instead of convolution. The weighted summation may be viewed as a moving average without division. In the case of a weighted summation, the summation window size may be determined by the non-zero components of the filter function. The magnitude of the non-zero components of the filter function may be considered as weight values to be assigned to the current measurements for summation. The convolution may also be viewed as a weighted summation with the weight f(n−k) for c(k).

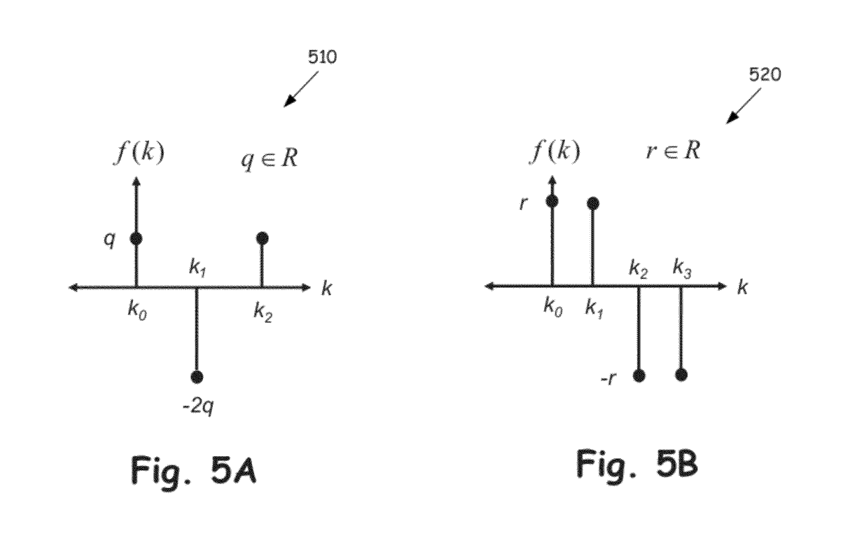

FIGS. 5A and 5B illustrate noise filter functions utilized in an embodiment of a defect current detection process, apparatus, or system. As illustrated, only non-zero signal components are shown, and zeros may be assumed elsewhere. It can be shown that the filter functions 510 and 520 are possible solutions to the convolution equation 430 illustrated in FIG. 4, and thus that these filter functions satisfy the filter function criteria.

In practice, the I_{c}(k) is not ideal, and varies across IDDQ current measurements. Based on a statistical assumption of I_{c}(k), the noise current effect may be reduced as the number of current measurements involved in a convolution increases or as non-zero components in f(k) increases. The increased number of f(k) components may operate to cancel out more noise components during convolution operations.

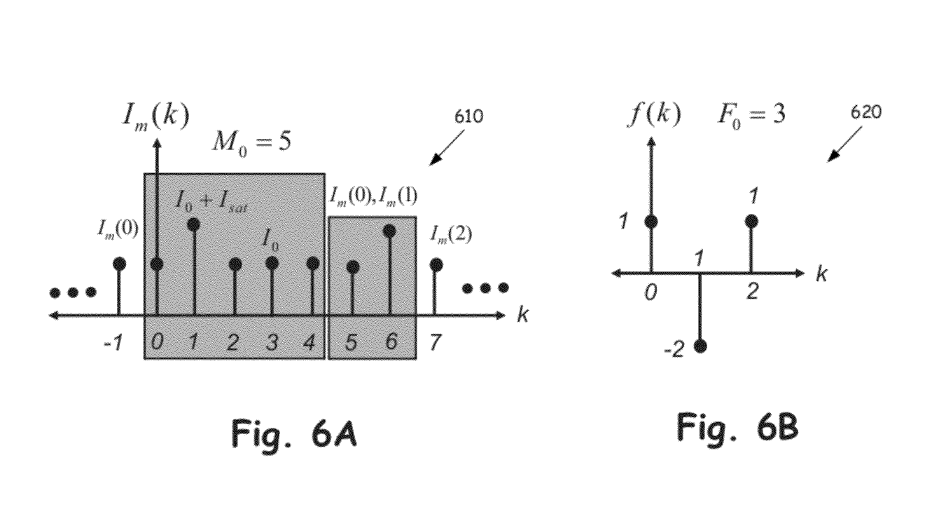

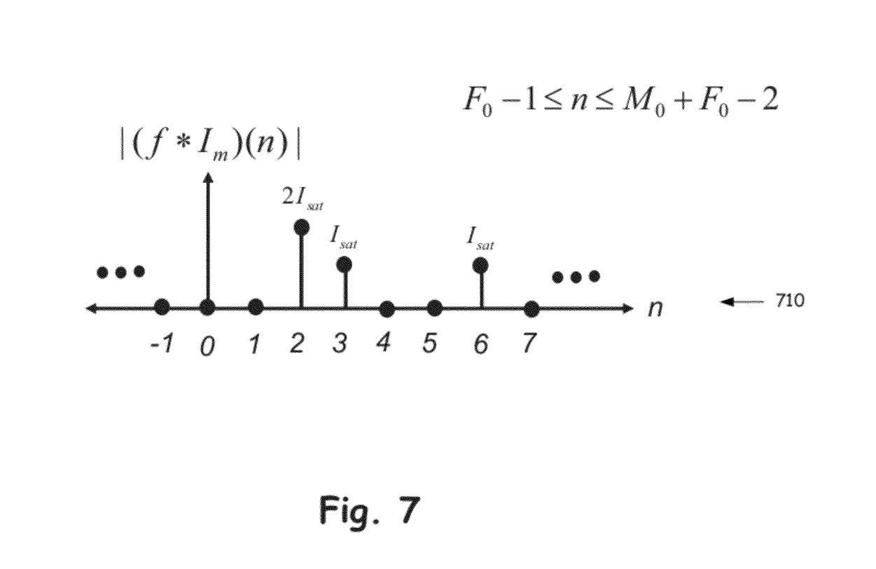

FIG. 6 and FIG. 7 illustrate an embodiment of a process for extraction of a defect current. For simplicity in discussion, a single Iₛₐₜ defect current is introduced and ideal common noise currents are assumed elsewhere. FIGS. 6A and 6B illustrate a measured current function Iₘ(k) 610 and filter function f(k) 620 in an embodiment of a process for extraction of a defect current. In such illustration, F₀ denotes the number of non-zero components in the filter function. The F₀ of filter function f(k) 620, for example, is 3. In this example, from a number of original current measurements denoted as M₀, the measured current signal Iₘ(k) in FIG. 6 may be constructed as follows:

$${I}_{m} ( k ) = \{ \begin{matrix}{I}_{m} ( 0 ) , & if k < 0 \\ {I}_{m} ( k ) , & if 0 \leq k < {M}_{0} \\ {I}_{m} ( k ( mod {M}_{0} ) ) , & if {M}_{0} \leq k\end{matrix} \qquad [ 3 ]$$

Where the k (mod M₀) denotes “k modulo M₀”.

In this example, from the set of original current measurements, Iₘ(0) is assigned to Iₘ(k) for k<0. To allow convolution to complete within the original measurements, the entire measured currents are repeated at the end of the current measurements. The convolution can either be performed indefinitely for any k or stopped after one cycle (i.e. k=M₀+F₀−2) as in FIG. 6.

FIG. 7 illustrates an embodiment of convolution in a method to recover or extract defect current. In some embodiments, an extracted defect current may be compared with a test limit or threshold to determine whether the DUT is deemed to be defective. In some embodiments, a process includes performing a convolution operation of Iₘ(k) with f(k) to observe defect current. In this example, convolution is performed in a range of F₀−1≦n≦M₀+F₀−2.

In some embodiments, common noises are removed by f(k) and the defect current Iₛₐₜ is amplified. An absolute value of a convolution is taken in order to recover a magnitude of a defect current. In some embodiments, convolution with the filter function is employed to amplify the defect currents and to remove common noise current.

However, in practice, the common noise current is not zero. In some embodiments, a filter function may be utilized to indicate a validity condition of defect current extraction. For example, if the noise current of the left and right neighbor points are closer to twice of the middle, then more defect current may be observed. If the validity condition holds, then the noise effect |I_{c}(4)−2I_{c}(5)+I_{c}(6)|, for example, can be significantly smaller than 2*Iₛₐₜ. If the validity condition does not hold, the f(k) may include a larger number of non-zero components to keep the noise effect reduced.

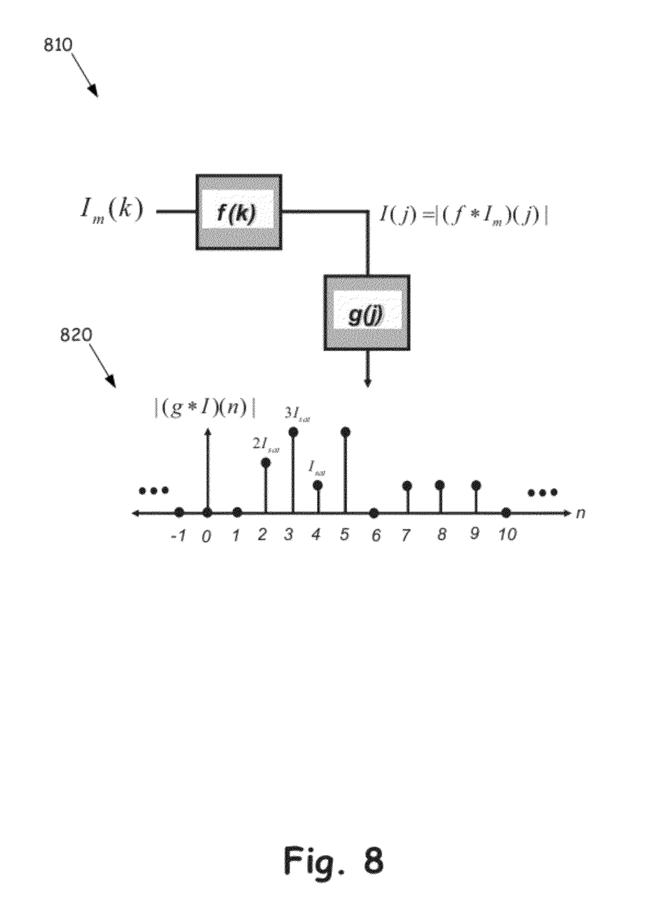

FIG. 8 illustrates multiple filter functions applied in series in an embodiment of a process to reduce noise currents. For example, the filter functions f(k) and g(k) in system 810 may include the functions illustrated in FIG. 5, which may be utilized with an assumption that q≧1 and r≧1. In general, the filter functions f(k) and g(k) may be the same or different function, or may be any number of other filter functions. In some embodiments, for an intermediate current function I(j) that can be obtained from convolution of Iₘ(k) with f(k), the example depicted in example (a) 710 may be applied. As shown in FIG. 8, the filter function g(j) may be applied to further amplify the amplified current in I(n) 820. In this example, there are total of 6 Iₛₐₜ currents presented in I(j) and 12 Iₛₐₜ currents in |(g*I)(n)|. Also, the unfiltered noise current from f(x) can be reduced further because convolution with the filter function g(j) can further reduce the unfiltered noise currents that escape in comparison with f(k). Increased numbers of current measurements are also involved in calculation of |(g*I)(n)| where I(j)=|(f*Iₘ)(j)|.

In some embodiments, defect current can further be amplified by aggregating amplified currents whose amplitude is above a certain threshold denoted as δIₛₐₜ, where δ is a real number. The aggregated current may be denoted as I_{A} and can also be measured in units of Iₛₐₜ, i.e. I_{A}/Iₛₐₜ units. The I_{A}/Iₛₐₜ measures how many saturation currents there are in I_{A}. In some embodiments, the aggregated current I_{A} may be used to determine whether the DUT is deemed to be defective or defect-free. For example, if δ=1.0, the aggregated current of the |(g*I)(n)| signal illustrated in FIG. 8 is I_{A}=12*Iₛₐₜ. In some embodiments, if the test limit or threshold for I_{A} is less than 12*Iₛₐₜ, the DUT may be determined to be defective.

In some embodiments, a method to obtain I_{A} is illustrated in equation [4]:

Input: |(f*y)(n)| for all n

I_{A}=0;

for (0≦n≦No−1) {

if I_{A}=I_{A}+|(f*y)(n)|; }}

Output: I_{A} [4]

In some embodiments, the calculation of I_{A} involves conditional summation of |(Iₘ*f)(n)| for all n. The amplified currents larger than the threshold δIₛₐₜ are added to I_{A}. Otherwise, the currents are ignored. Any size of defective current would be aggregated if δ=0. In an example, a single defect current in the Iₘ(k) presented in FIG. 6, element 610, is amplified 12 times by the convolution and aggregation. The noise current can also be reduced to |(Iₙ*g)(n)| where Iₙ(j)=|(I_{c}*f)(j)|. In some embodiments, unfiltered noise currents included in the amplified currents with amplitudes that are either below or above threshold amounts are removed or and the remaining noise currents are averaged out respectively during aggregation.

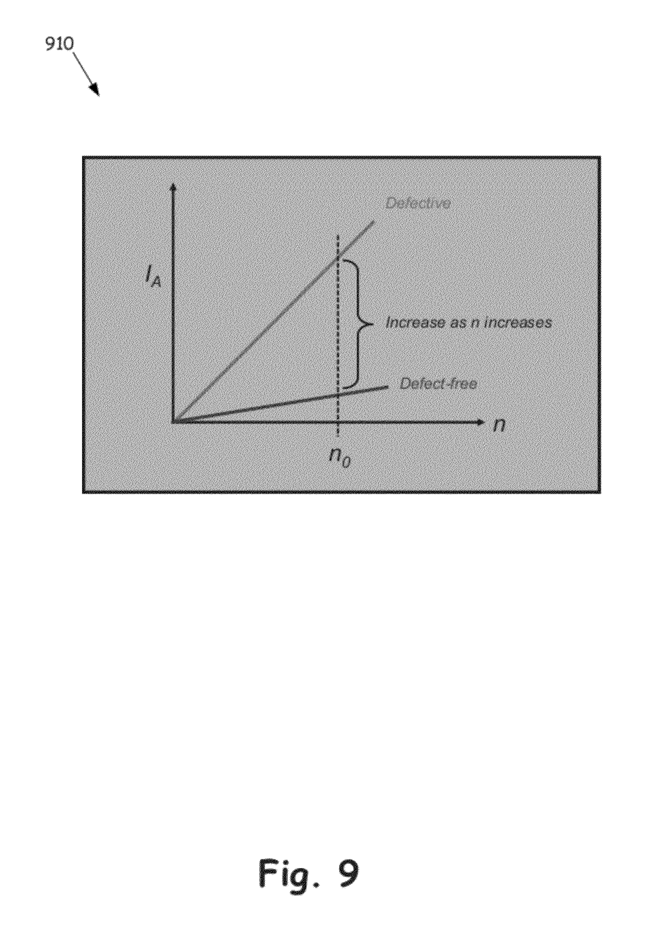

FIG. 9 is an illustration of defect and noise currents addressed in an embodiment of defect current detection. If a noise current can be reduced, the difference between defect current and noise current increases as increased numbers of current measurements that capture defects are processed in convolution, with the aggregation being as shown in the illustrated graph 910 in FIG. 9.

In some embodiments, a process may be implemented to increase n without measuring additional currents. Measuring current can be an expensive operation in terms of test time, which can greatly increase total test costs. In some embodiments, the increase in n may be achieved by one or more of the following approaches: permutation of measured current function; and employment of multiple filter functions. Such approaches are based on the observation that the result of a convolution operation is order sensitive. If components of the original measured current function were reordered, convolution operated on the reordered measured currents can produce a different result. In some embodiments, the function Iₘ(k) thus may be extended by concatenating the original current measurements with the reordered or permutated ones. If a defect current was captured in the original current measurements, it can be amplified more in the extended measured current function Iₘ(k).

If, for example, ten current measurements were taken and three different permutations were concatenated to the original, convolution |((Iₘ*f)(n)| can be operated on 40 current measurements instead of 10. In some embodiments, if defect currents are captured in an original set of current measurements, concatenation of permutations may be utilized to significantly increase the I_{A}, and assist to differentiate defective parts from defect-free parts, as illustrated in FIG. 9.

In some embodiments, amplification by convolution on reordered current measurements using the same filter function may similarly be achieved by convolution on the original current function using multiple filter functions. Thus, multiple filter functions operated in parallel may be employed to mimic the role of different permutations.

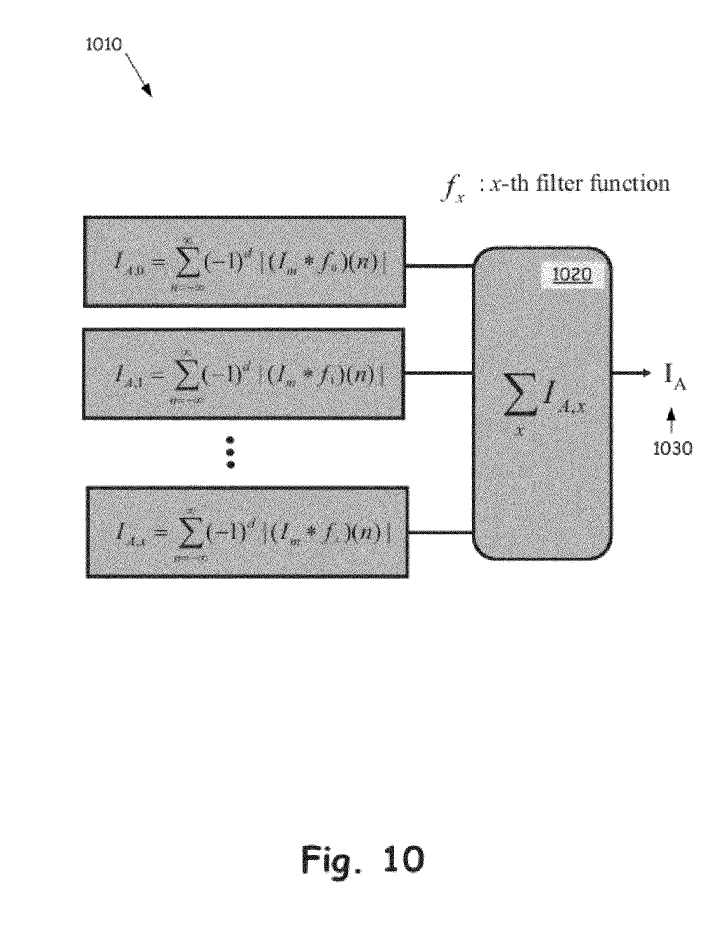

In some embodiments, a set of different filter functions may similarly be obtained from permutation of original filter function. FIG. 10 is an illustration of an embodiment of a method for application of filtering to current measurements. In some embodiments, a set of filter functions may convolute with the original measured current function in parallel, such as shown in element 1010 in FIG. 10. The aggregation method is as illustrated in FIG. 8, with filter function fₓ(k) denoted as I_{A,x}. Each aggregated current can be added 1020 to produce the total aggregated current I_{A} 1030. In some embodiments, the aggregated currents can also be combined using other operations instead of summation.

In some embodiments, an advantage of employing multiple filter functions may be that both convolution and aggregation can concur with current measurement at automatic test equipment (ATE). In some embodiments, as soon as current is measured from the ATE, both convolution and aggregation may simultaneously be performed. In some embodiments, amplified defect currents by different filter functions may, for example, be tested for defect at every step of convolution. Further, at the end of convolution, the I_{A} value can immediately be available. In some embodiments, if the current I_{A} is significantly larger than expected, the DUT may be determined to be defective.

In the operation of defect current detection, noise current reduction is dependent upon the filter function that is utilized. However, embodiments are not limited to a certain filter function or approach to generating such filter function. Numerous qualified filter functions satisfy the criteria illustrated in FIG. 4, and multiple different approaches to generate filter functions that satisfy such criteria.

In some embodiments, filter function generation may be based on random number generation and an n-th order Ψ recurrence equation. A filter function obtained from random numbers, referred to as random filter function, may be utilized to reduce or smooth out noise currents while amplifying the defect current. A filter function that is based on an n-th order recurrence equation can reduce noise current and amplify the defect current through the higher order difference operations. For a single defect current, included in the Iₘ(k) signal shown in FIG. 6A, the recurrent filter function may be utilized to amplify the defect current by more than 2^{k} times.

In some embodiments, filter functions obtained from two different approaches may be applied one after another, as illustrated in FIG. 8, in order to amplify defect currents. For example, the random filter function can be applied to the current measurements to amplify the defect current and to smooth out noise currents. The recurrent filter function can be applied to the amplified current signal that results from convolution of measured current with the random filter function. For example:

Input: array H(N₀)(H(n)>0 for 0≦n<N₀)

for 0≦n≦N₀−1,

A=rand(min, max, −0);

for 0≦h≦H(n)−1,

f(2N₀n+h)=A;

f(2N₀n+(h+H(n)))=−A;

Output: f(k), 0≦k≦2(ΣH(k))−1 [5]

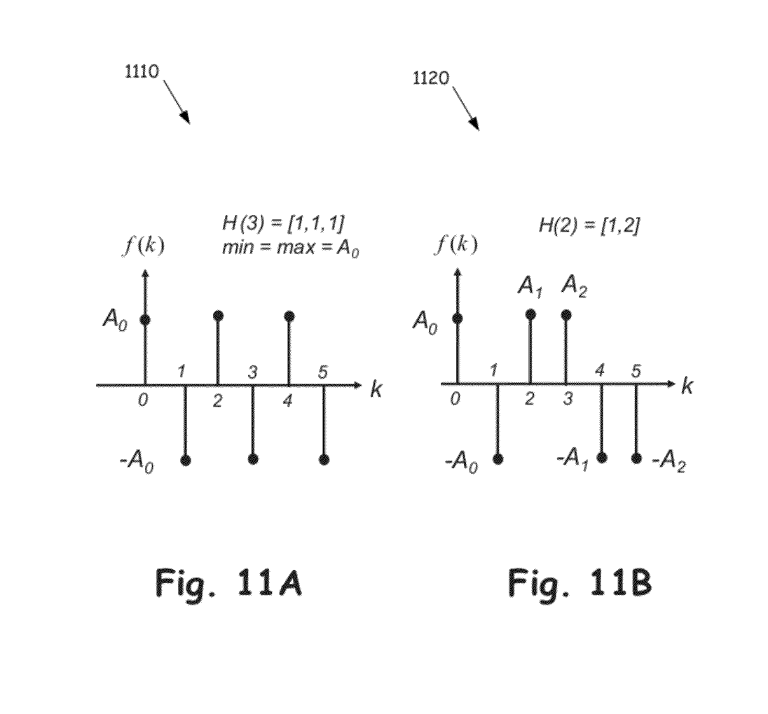

FIGS. 11A and 11B illustrate random filter function generation in an embodiment of defect current detection. In some embodiments, the generation of a random filter function accepts an input of a one-dimensional array H(N₀) of size N₀ and produces the function f(k). In such generation of a filter function, each element of an array of H(n) can provide the 2H(n) number of non-zero f(k) components. In some embodiments, an amplification factor, denoted as A, may be provided as an input or may be generated internally using a random number generation function, denoted as rand. The random number generation function rand(min, max, −0) generates a random number between minimum value “min” and maximum value “max”, excluding the value of zero (−0).

For 0≦h≦H(n)−1, the amplification factor may be assigned to f(h) and to f(h+H(n)) with the sign of the amplification factor inverted. The examples of f(k) depicted in FIG. 11 assume rand(A₀, A₀, −0), and input H(3)=[1,1,1] for FIG. 11A (filter function 1110) and H(2)=[1,2] for FIG. 11B (filter function 1120). It may be shown that the resulting filter function f(k) satisfies the filter function criteria. The obtained filter functions can amplify defect currents during convolution while reducing noise currents buried in the measured currents.

In some embodiments, selection of filter function may improve amplification in I_{A} and observability of defect currents. Further, inclusion of both even and odd number in H(N₀) can increase observability of defect currents if amplification is uniform. The amplification is uniform if the same magnitude of amplification factor is used in the f(k). The magnitude of amplification factor may be defined as an absolute value of the amplification factor A, denoted as |A|. If both even and odd numbers were included in the H(N₀), the defect currents may be observed regardless of whether they are odd or even number of measurements apart. Thus, such currents can be observed more often and amplified in aggregation. For example, when defect currents are captured in the measured currents Iₘ(j) and Iₘ(j+D) where D is odd, those defect currents may not be observed if the filter function 1110 shown in, for example, FIG. 11A is employed. The same defect currents, however, may not be masked if the amplification in the filter function 1110 shown in FIG. 11A is non-uniform, or if the filter function 1120 shown in FIG. 11B is employed.

In some embodiments, a process can generate the filter functions with both uniform and non-uniform amplifications by providing min and max to the function rand(min, max, −0).

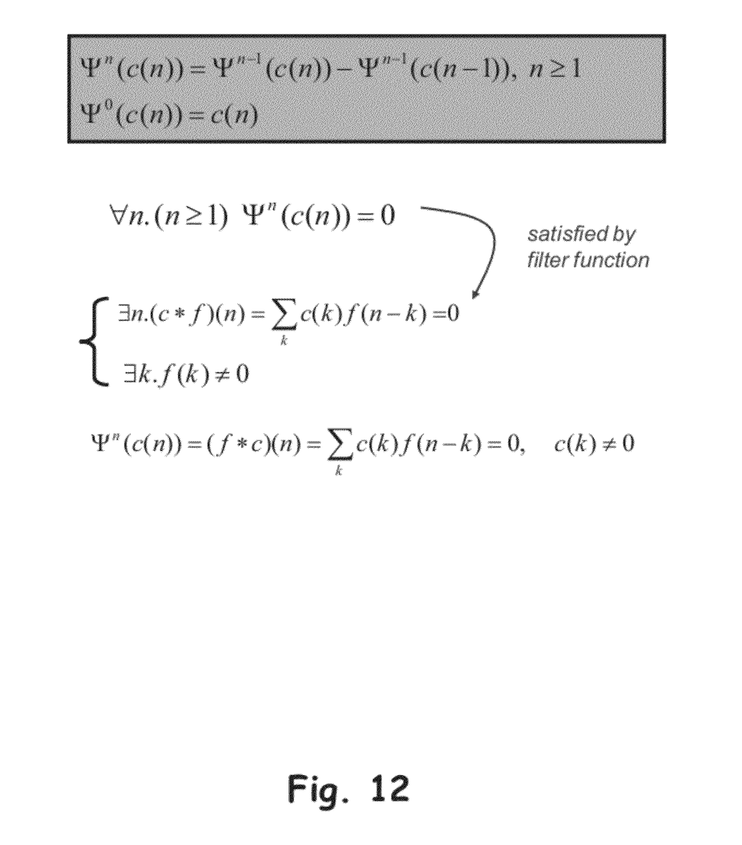

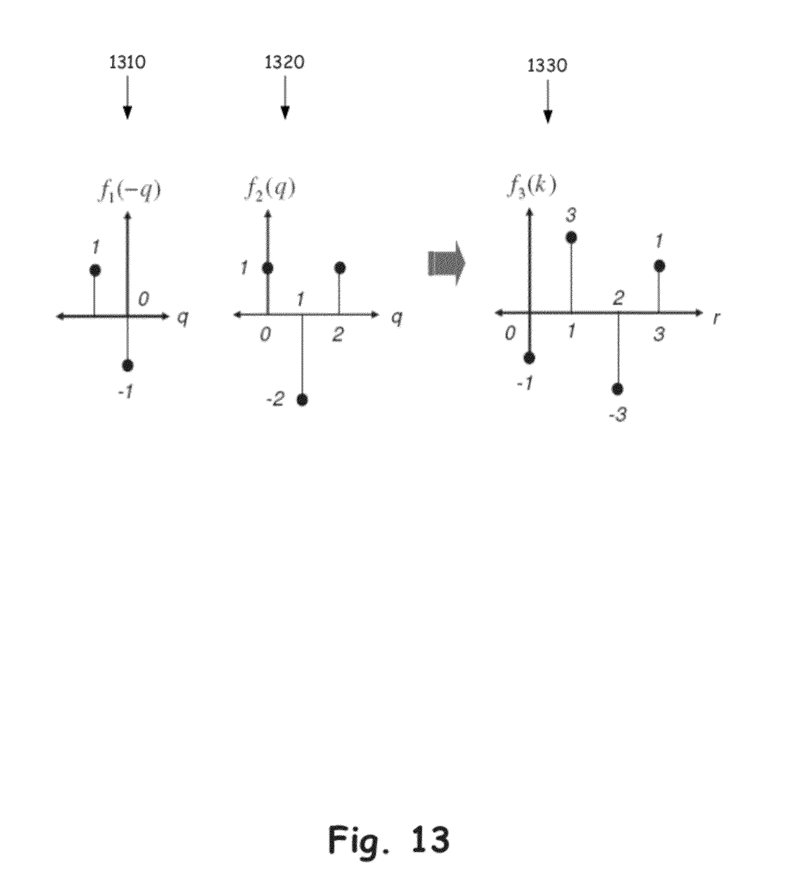

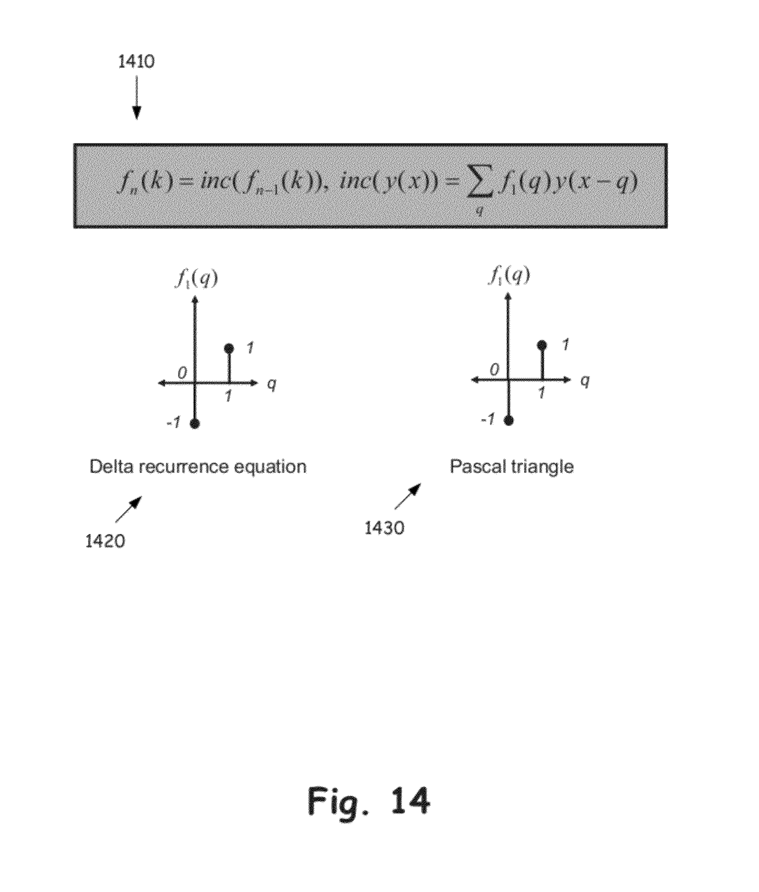

In some embodiments, the filter function f(k) can also be generated using an n-th order Ψ recurrence equation. Generation of the f(k) using n-th order Ψ recurrence equation is illustrated in FIG. 12, FIG. 13, and FIG. 14. In some embodiments, the n-th delta recurrence equation amplifies defect current through the higher order of recurrence relations, while reducing noise current effect from the satisfied filter function criteria.

FIG. 12 illustrates a recurrence equation for an embodiment of a method, apparatus, or system providing defect current detection. From the given recurrence equation, Ψⁿ(c(n)) is expressed recursively as Ψⁿ⁻¹(c(n))−Ψⁿ⁻¹(c(n−1)). The Ψⁿ(c(n)) can satisfy the filter function criteria because c(n)=c(n−1)=I₀ and hence c(n)−c(n−1)=0. Thus, it can be shown that:

Ψⁿ(c(n))=Ψⁿ⁻¹(c(n))−Ψⁿ⁻¹(c(n−1))=0 [6]

The equation expressing Ψⁿ(c(n)) implies that summation of coefficients of finite difference equation resulted from its expansion is also zero. This means that if the Ψⁿ(c(n)) can be viewed as coefficients convoluted with c(n) signal, the coefficients of which be considered as a filter function. In some embodiments, a generation method, therefore, is to generate coefficients of expansion of Ψⁿ(c(n)) for arbitrary n. If expansion of Ψⁿ(c(n)) is considered as a convolution, the filter function of F₀=3, for example, can be obtained from Ψⁿ(c(n)) for n=F₀−1=2 as follows:

$$\begin{matrix}{Ψ}^{2} ( c ( 2 ) ) = Ψ ( c ( 2 ) ) - Ψc ( 1 ) \\ = ( c ( 2 ) - c ( 1 ) ) - ( c ( 1 ) - c ( 0 ) ) \\ = c ( 0 ) - 2 c ( 1 ) + c ( 2 ) \\ = f ( 2 - 0 ) c ( 0 ) + f ( 2 - 1 ) c ( 1 ) + f ( 2 - 2 ) c ( 2 ) ,\end{matrix} \\ note that f ( n - k ) . \qquad [ 7 ]$$

From such calculation in Equation [7], the resulting filter function may be a finite difference equation with coefficients 1, −2, 1. Thus, the desired f(k)=1, −2, 1 for k=2, 1,0 respectively, FIG. 6B illustrates the resulting filter function. In such example, all common noise current components are removed while the defect current is amplified by factor of 2. Such amplification is due to the fact that the proposed recurrence equation can extract defect current with respect to both left and right side neighbor signal components. If the amplification factor were larger, the amplified defect current would then be higher. In such calculation, a constraint is that the noise current is required to be reduced simultaneously.

FIG. 13 illustrates a filter function for higher order k defined using convolution for an embodiment of a method, apparatus, or system providing defect current detection. The filter function fₙ may be obtained from convolution of filter functions fᵢ with fⱼ where n=i+j. An example of a determination of fₙ for n=3 is depicted in FIG. 13. Convolution of f₁ (1310) with f₂(1320) produces f₃(k) (1330), where f₃(k)=1,3,−3,−1 for k=0, 1, 2, 3 respectively. However, masking of defect currents may not occur because the amplification is not uniform.

The definition depicted in FIG. 13 is operational, and reflects how the higher order filter functions may actually be computed. In a special case where i=1, the filter function f₁ may be used to generate n-th order filter function by convoluting f₁ with fₙ₋₁. In such case, f₁ combined with convolution may be considered as an increment operator denoted as inc. Further, the filter function f₁ may be referred to as an operator function. When the operator is applied to any filter function, the operator increments the filter function order. Thus, the filter function fₙ may be obtained by applying the operator n times.

FIG. 14, illustrates calculation of coefficients in an embodiment of a process for defect current detection. From an operator function point of view, as shown in FIG. 14, calculation 1410 of coefficients for the n-th order Ψ recurrence equation (illustrated as Delta recurrence equation 1420) is identical to that of Pascal's triangle 1430 to find coefficients in the binomial expansion of (−x+y)ⁿ. Thus, Pascal's triangle may also be also be generated by convolution as provided in FIG. 13 or by the inc operator with operator function as provided in FIG. 13, Pascal's triangle is a geometrical arrangement of the binomial coefficients in a triangle and is often generated from binomial expansion using combination, which involves a factorial. In some embodiments, the convolution approach for generation of coefficients, however, may be more efficient and provide a more intuitive operation from a computational point of view.

An embodiment of an IDDQ test procedure is presented here in equation [8], with an assumption that the determined filter function f(k) contains F₀ number of non-zero components:

1. I_{A}=0; f(k)]=noise filter function;

2. For n=0 to M₀+F₀−1 do {

2.1. if (n<M₀) {Apply test pattern n;

Iₘ(n)=measure current from ATE;

if (Iₘ(n)≧power short current limit) {fail test;}}

2.2. if (F₀−1≦n<M₀+F₀−1) {I(n)=|(Iₘ*f)(n)|;

if (I(n)>convolution test limit) {fail test;}

else {if (I(n)>δIsat) {I_{A}=I_{A}+I(n); }}}

3. if (I_{A}>aggregation test limit) {fail test;} [8]

In some embodiments, the IDDQ test procedure allows convolution and aggregation to be concurrent with current measurement at ATE. Each current measurement is tested for power short catastrophic defect. In some embodiments, defect current caused by a power short can be very significant and noticeable immediately. If the device under test (DUT) is free of catastrophic power defects, each measured current at the tester can be used to construct measured current function Iₘ(n).

In some embodiments, if the first current measurement Iₘ(0) is available from the tester, the Iₘ(n) for all n<0 or −F₀<n<0 may be constructed by assigning Iₘ(n)=Iₘ(0). In some embodiments, the IDDQ test procedure assumes M₀ number of current measurements and M₀>F₀. If (F₀−2)-th current measurement are available, the current measurements from 0-th to (F₀−2)-th (denoted as Iₘ[0:F₀−2]) or its permutation may be copied to the Iₘ[M₀:M₀+F₀−2]. In an alternative, the Iₘ(M₀+F₀−2) can be assigned to the Iₘ(n) for all n<M₀+F₀−2, if needed. Convolution and aggregation may be initiated when the (F₀−1)-th current measurement is available, as illustrated in FIG. 7. In some embodiments, convolution and aggregation, however, can be initiated as early as when 0-th current measurement (Iₘ(0)) is available, with an assumption that Iₘ(n)=Iₘ(0) for n<0. In some embodiments, each stage of convolution result or amplified current is compared against the convolution test limit to decide if the DUT is defective. When the final current Iₘ(M₀−1) is measured at the tester, construction of the current signal Iₘ(n) can be completed. In some embodiments, a test may also be completed by carrying out convolution and aggregation on the remaining Iₘ[M₀:M₀+F₀−2]. If all convolutions are finished, the I_{A} is compared to the test limit to detect defects.

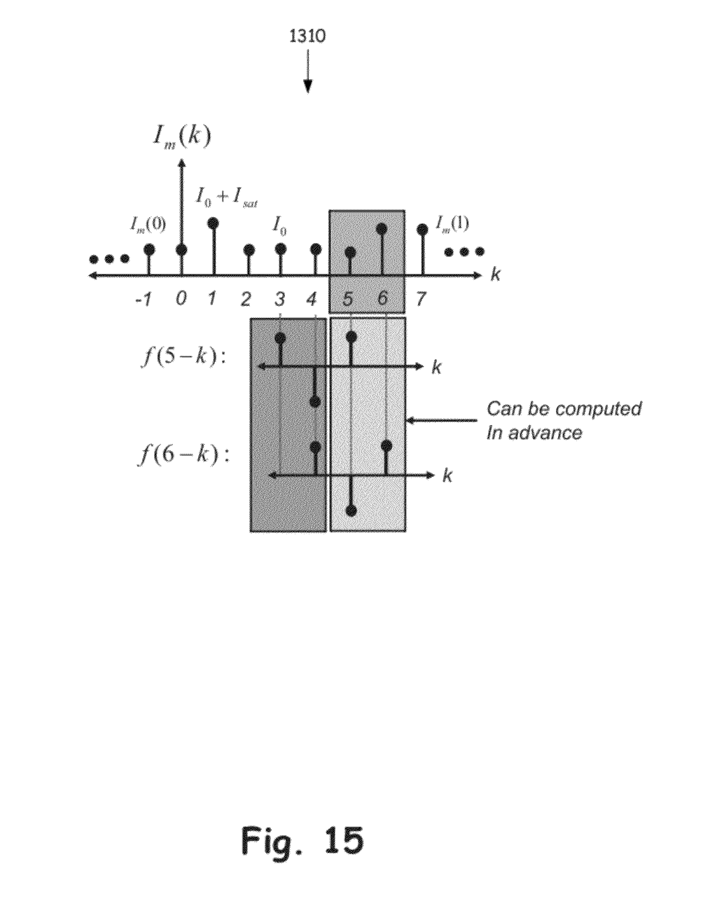

FIG. 15 illustrates a filter function for an embodiment of detection of defect currents. In some embodiments, convolution and aggregation on the appended current measurements Iₘ[M₀:M₀+F₀−2] may be carried out in advance so that both convolution and aggregation can be completed when the last current measurement Iₘ(M₀−1) is available. Because the filter function is known, such as the example illustrated in FIG. 15, partial convolution and aggregation may be performed in advance for Iₘ[M₀:M₀+F₀−2] and completed when the needed current measurements are available. In case of n=5 in FIG. 15, the f(0) and Iₘ(5) which is Iₘ(0) can be multiplied in advance and wait for Iₘ(4])×f(1) and Iₘ(3)×f(2) to complete convolution and aggregation. In this manner, the required multiplication and addition may be carried out as soon as the measured current is available from the tester. Similarly, for n=6, the sum of two products Iₘ(5)×f(1) and Iₘ(6)×f(0) may be calculated when Iₘ(0) and Iₘ(1) are available and convolution can be completed when the final current Iₘ(M₀−1) is measured.

In some embodiments, the IDDQ procedure may be extended to accommodate multiple filter functions, such as, for example, functions illustrated in FIGS. 8 and 11. For the filter functions applied in series as in FIG. 8, when the I(n) can be obtained, the same IDDQ test procedure can recursively be applied to I(n) as if it were Iₘ(n) until all filter functions are applied. For example, in FIG. 8, the IDDQ procedure can be applied to f(k) and Iₘ[0:M₀−1] in order to obtain I(n) which can be considered as Iₘ[0:M₀′−1]. Then, the IDDQ procedure may again be applied to I(n) and g(j) in order to obtain a test result.

In some embodiments, to similarly address filter functions operated in parallel such as in FIG. 11, step 2.2 of Equation [8] may be duplicated for multiple filter functions. In some embodiments, each aggregated current may be summed up before proceeding to step 3 of Equation [6]. In an alternative, step 3 may be duplicated to check the test limit for each individual aggregated current I_{A,x} separately before the currents are summed up to produce the total aggregate current I_{A}.

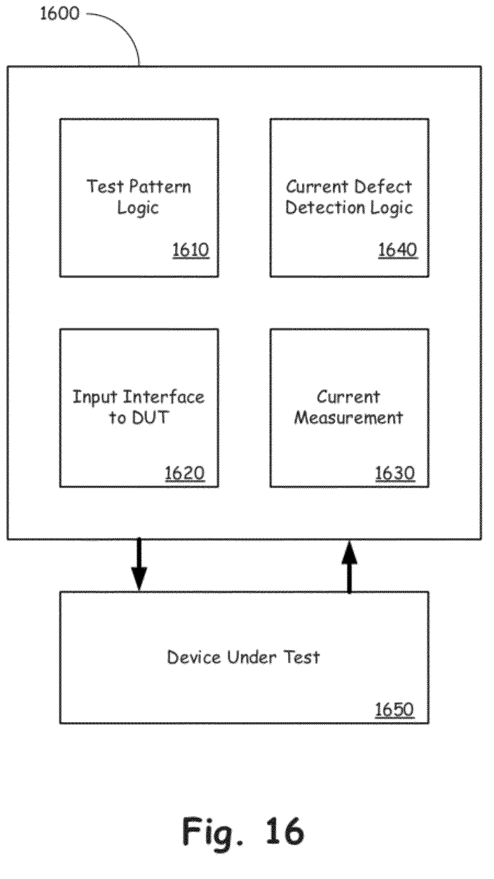

FIG. 16 illustrates an embodiment of an apparatus or system for the detection of defective components utilizing IDDQ measurements. In this illustration, a testing apparatus or system 1600 is couple with a device under test (DUT) 1650. The DUT 1650 may include a semiconductor device generated using advanced manufacturing processes, such as such a 0.1.3 μm or smaller device, but embodiments are not limited to the testing of any particular device. In some embodiments, the testing apparatus or system 1600 includes logic to create test patterns 1610 for the testing of the DUT 1650. The generated test patterns may include patterns to apply quiescent current in order to measure currents in paths though transistor devices in the DUT 1650. In some embodiments, the testing apparatus or system 1600 further includes an input interface 1620 to provide the generated test patterns to the DUT 1650.

In some embodiments, the testing apparatus or system 1600 further includes a module or unit for measurement of currents 1630 for the DUT 1650. In some embodiments, the current measurements are used by a logic for current defect detection 1640. In some embodiments, the module operates to remove common leakage currents from measured values, while amplifying detected defect currents, including use of current aggregation. In some embodiments, the apparatus or system 1600 utilizes the detection of defect currents to make a determination whether or not the DUT 1650 is defective.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments of the present invention may include various processes. These processes may be performed by hardware components or may be embodied in computer program or computer-executable instructions, which may be used to cause a general-purpose or special-purpose processor or logic circuits programmed with the instructions to perform the processes. Alternatively, the processes may be performed by a combination of hardware and software.

Portions of various embodiments of the present invention may be provided as a computer program product, which may include a non-transitory computer-readable storage medium having stored thereon computer program instructions, which may be used to program a computer (or other electronic devices) to perform a process according to the embodiments of the present invention. The computer-readable medium may include, but is not limited to, floppy diskettes, optical disks, compact disk read-only memory (CD-ROM), and magneto-optical disks, read-only memory (ROM), random access memory (RAM), erasable programmable read-only memory (EPROM), electrically-erasable programmable read-only memory (EEPROM), magnet or optical cards, flash memory, or other type of computer-readable storage medium suitable for storing electronic instructions. Moreover, the present invention may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present invention. It will be apparent to those skilled in the art that many further modifications and adaptations can be made. The particular embodiments are not provided to limit the invention but to illustrate it. The scope of the embodiments of the present invention is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example of the present invention. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments of the present invention, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims are hereby expressly incorporated into this description, with each claim standing on its own as a separate embodiment of this invention.

1. A method comprising:
applying a test pattern of inputs to a device, the device including one or more CMOS (Complementary Metal-Oxide Semiconductor) transistors;
obtaining a plurality of current measurements for the device, each of the plurality of current measurements being a measurement of a current after applying an input of the test pattern to the device;
applying a filter function to the plurality of current measurements, applying the filter function including separating defect current values from the current measurements; and
determining whether a defect is present in the device based on a comparison of the defect current values with a threshold value.

2. The method of claim 1, wherein each current measurement includes a signal component and a noise component, the signal component being the defect current and the noise component including leakage current of the one or more CMOS transistors.

3. The method of claim 2, wherein applying the filter function includes:
amplifying the defect currents in the current measurements and reducing leakage current values in the measurements; and
aggregating amplified defect currents.

4. The method of claim 3, wherein amplifying the defect currents includes performing a convolution of the plurality of current measurements.

5. The method of claim 3, wherein amplifying the defect currents includes performing a weighted summation of the plurality of current measurements.

6. The method of claim 3, wherein aggregating the amplified defect currents includes aggregating amplified current values that are above a certain threshold.

7. The method of claim 1, wherein applying the filter function includes applying a plurality of filter functions.

8. The method of claim 1, wherein applying the filter function to the plurality of current measurements for the device includes permutation of the current measurements to generate permutated current results.

9. The method of claim 8, wherein applying the filter function includes concatenating the current measurements with the permutated current results.

10. The method of claim 1, further comprising generating the filter function.

11. The method of claim 10, further comprising generating the filter function based on random number generation.

12. The method of claim 10, wherein generating the filter function includes utilization of an n-th order Ψ recurrence equation.

13. A test apparatus comprising:
an interface for a device under test, the connection to apply a set of inputs to a device containing one or more CMOS (Complementary Metal-Oxide Semiconductor) devices;
logic to apply a test pattern of inputs to the device under test;
a current measurement unit to measure a current of the device for each input of the set of inputs and produce a plurality of current measurements;
logic to separate defect current from the current measurements including application of a noise filter function to the current measurements; and
logic to determine existence of a defect in the device under test based at least in part on the defect current.

14. The apparatus of claim 13, wherein the logic to separate the defect current includes logic to amplify defect current values and to reduce noise current values.

15. The apparatus of claim 14, wherein the amplification of the defect current values includes a weighted summation of the current measurements.

16. The apparatus of claim 14, wherein the logic to separate the defect current includes logic to convolve the current measurements with, the noise filter function to separate defect currents, and to aggregate the defect currents for the device under test.

17. The apparatus of claim 16, wherein the aggregation of the defect currents includes aggregation of amplified defect current values that are above a certain threshold.

18. The apparatus of claim 13, wherein application of the noise filter function includes applying a plurality of filter functions.

19. The apparatus of claim 13, wherein application of the noise filter function includes permutation of the current measurements to generate permutated current results.

20. The apparatus of claim 19, wherein application of the noise filter function includes concatenating the current measurements with the permutated current results.

21. A non-transitory computer-readable storage medium having stored thereon data representing sequences of instructions that, when executed by a processor, cause the processor to perform operations comprising:
applying a test pattern of inputs to a device, the device including one or more CMOS (Complementary Metal-Oxide Semiconductor) transistors;
obtaining a plurality of current measurements for the device, each of the plurality of current measurements being a measurement of a current after applying an input of the test pattern to the device;
applying a filter function to the plurality of current measurements, applying the filter function including separating defect current values from the current measurements; and
determining whether a defect is present in the device based on a comparison of the defect current values with a threshold value.

22. The medium of claim 21, wherein each current measurement includes a signal component and a noise component, the signal component being the defect current and the noise component including leakage current of the one or more CMOS transistors.

23. The medium of claim 22, wherein applying the filter function includes:
amplifying the defect currents in the current measurements and reducing leakage current values in the measurements; and
aggregating amplified defect currents.

24. The medium of claim 23, wherein amplifying the defect currents includes performing a convolution of the plurality of current measurements.

25. The medium of claim 23, wherein amplifying the defect currents includes performing a weighted summation of the plurality of current measurements.

26. The medium of claim 23, wherein aggregating the amplified defect currents includes aggregating amplified current values that are above a certain threshold.

27. The medium of claim 23, wherein applying the filter function includes applying a plurality of filter functions.

28. The medium of claim 23, wherein applying the filter function to the plurality of current measurements for the device includes permutation of the current measurements to generate permutated current results.

29. The medium of claim 28, wherein applying the filter function includes concatenating the current measurements with the permutated current results.

30. The medium of claim 23, further comprising instructions that, when executed by the processor, cause the processor to perform operations comprising:
generating the filter function based on random number generation.
